(19) United States
(12) Patent Application Publication
(10) Pub. No.: US 2004/0032207 A1
(43) Pub. Date: Feb. 19, 2004

(54) Electroluminescent display device

(75) Inventors: Toru Sasatani, Motosu-gun (JP); Tetsuji Omura, Ogaki-shi (JP); Hideki Matsuoka, Gifu-shi (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Osaka (JP)

(21) Appl. No.: 10/423,059

(22) Filed: Apr. 25, 2003

(30) Foreign Application Priority Data
Apr. 26, 2002 (JP) 2002-127422

(51) Int. Cl. H05B 33/00

(52) U.S. Cl. 313/506

(57) ABSTRACT

In a sealing structure of an electroluminescent display device, there are inhibited a temperature rise of a display panel on a light-emission of an EL element and thus deterioration of the EL element. The structure of the invention has a first glass substrate provided with an electroluminescent device on a surface thereof, a second glass substrate attached to the first glass substrate with sealing resin, and a desiccant layer formed on a pocket portion of the second glass substrate, and a high heat conductive layer made of a metal sheet etc covering a surface of the desiccant layer.

### BACKGROUND OF THE INVENTION

1. Field of the Invention

This invention relates to an electroluminescent display device, particularly to a sealing structure of the electroluminescent display device.

2. Description of the Related Art

In recent years, electroluminescent (hereafter, referred to as EL) display devices with EL elements have been receiving an attention as a display device replacing a CRT and an LCD.

Since the EL element is sensitive to moisture, there has been known an EL display panel structure in which the EL element is covered with a metal cap or a glass cap coated with a desiccant. FIG. 8 is a cross-sectional view showing such a conventional structure of the EL display panel.

A first glass substrate 70 has a display region having many EL elements 71 thereon. The first glass substrate 70 is attached to a second glass substrate 80 working as a cap with sealing resin 75 made of an epoxy resin. The second glass substrate 80 includes a concave portion 81 (hereafter, referred to as a pocket portion 81) in a region corresponding to the display region. The pocket portion 81 is coated with a desiccant layer 82 for absorbing moisture.

Here, the forming of the pocket portion 81 is for securing a space between the desiccant layer 82 and the EL element 71, thereby preventing the EL element 71 from being contacted by the desiccant layer 82, which may cause damage to the EL element 71.

Since the EL element 71 is heated upon light-emission, the temperature of the first glass substrate 70 rises. This temperature rise cases an accelerated deterioration of the EL element 71, and results in a short life use time of the device.

### SUMMARY OF THE INVENTION

The invention provides an electroluminescent display device that includes a first substrate having an electroluminescent element thereon, a second substrate attached to the first substrate, a desiccant layer disposed on the second substrate so that the desiccant layer faces the first substrate, and a heat dissipation layer disposed on the desiccant layer and having a high thermal conductivity.

The invention also provides an electroluminescent display device that includes a first substrate having an electroluminescent element thereon, a second substrate attached to the first substrate, and a desiccant layer disposed on the second substrate so that the desiccant layer faces the first substrate. The desiccant layer includes a material of a high thermal conductivity.

The invention further provides an electroluminescent display device that includes a first substrate having an electroluminescent element thereon, a second substrate attached to the first substrate, and a heat dissipation layer disposed on the second substrate so that the heat dissipation layer faces the first substrate. The heat dissipation layer has a high thermal conductivity. The device also includes a desiccant layer disposed on the heat dissipation layer.

The invention also provides an electroluminescent display device that includes a first substrate having an electroluminescent element thereon, a second substrate attached to the first substrate, and means for dissipating heat generated by the electroluminescent element.

### BRIEF DESCRIPTION OF THE DRAWINGS

FIG. 1 is a plan view of an electroluminescent display device according to a first embodiment of the invention.

FIG. 2 is a cross-sectional view along line A-A′ of FIG. 1.

FIG. 3 is a perspective view of a high heat conductive layer of the first embodiment of the invention.

FIG. 4 is a cross-sectional view of an electroluminescent display device according to a second embodiment of the invention.

FIG. 5 is a cross-sectional view of an electroluminescent display device according to a third embodiment of the invention.

FIG. 6 is a plan view of a pixel of the organic EL display devices of the first, second and third embodiments.

FIGS. 7A and 7B are cross-sectional views of the pixel of FIG. 6.

FIG. 8 is a cross-sectional view of a conventional electroluminescent display device.

### DETAILED DESCRIPTION OF THE INVENTION

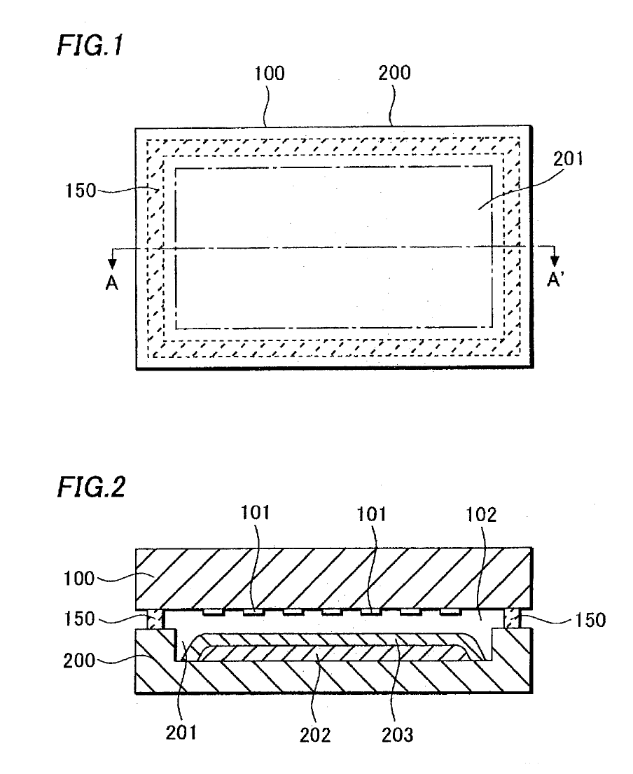

FIG. 1 is a plan view of an electroluminescent display device according to a first embodiment of the invention. FIG. 2 is a cross-sectional view along line A-A′ of FIG. 1.

A first glass substrate 100 (a display panel) has a display region having many EL elements 101 on a surface thereof. The thickness of the first glass substrate 100 is approximately 0.7 mm. In this display region, a plurality of pixels is disposed in a matrix and the EL element 101 is disposed in each of those pixels.

A second glass substrate 200 is a glass substrate for sealing the above mentioned first glass substrate 100 and its thickness is approximately 0.7 mm. This second glass substrate 200 includes a concave portion 201 (hereafter, referred to as a pocket portion 201) in a region corresponding to the display region, which is formed by etching. The depth of the pocket portion 201 is approximately 0.3 mm. There is coated on the pocket portion 201 a desiccant layer 202 for absorbing moisture. The desiccant layer 202 is formed, for example, by coating a solvent dissolved with powdered calcium oxide or barium oxide and a resin as an adhesive on a bottom of the pocket portion 201 and then hardening the solvent by UV irradiation or heating.

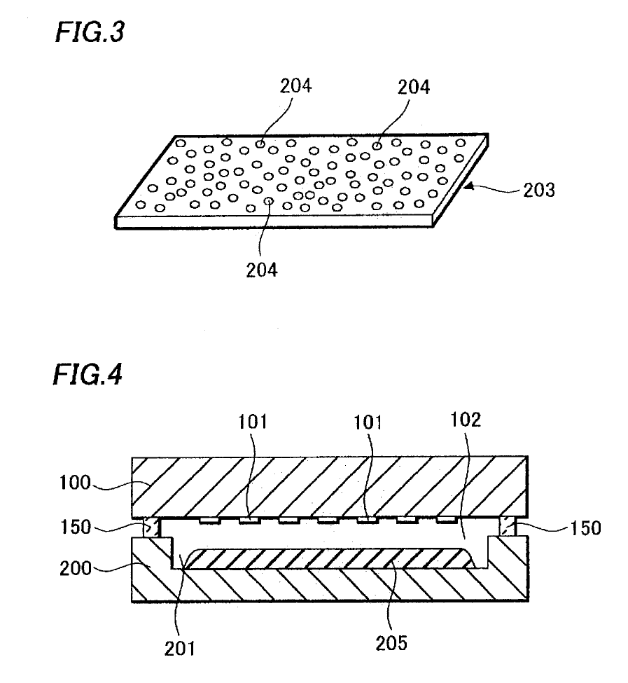

The desiccant layer 202 is covered with a high heat conductive layer 203. The high heat conductive layer 203 is formed of, for example, a metal sheet having a thickness of 10 to 100 micrometers. The metal sheet can be made of any metal, for example, Al (aluminum) and Cr (chromium). Furthermore, as shown in FIG. 3, the high heat conductive layer 203 preferably includes many air vents 204. This is for keeping air permeability of the desiccant layer 202 high to prevent its losing the function as a desiccant.

The first glass substrate 100 and the second glass substrate 200 are attached with sealing resin 150 made of an epoxy resin in a chamber of N₂ gas atmosphere. Thus, N₂ gas fills a space surrounded by the high heat conductive layer 203, the first glass substrate 100 and the sealing resin 105 to form an N₂ gas layer 102.

The electroluminescent display device of the invention has a structure in which the high heat conductive layer 203 is disposed between the desiccant layer 202 and the EL element 101. Therefore, heat generated upon light-emission of the EL element 101 is dissipated rapidly toward the second glass substrate 200 through the high heat conductive layer 203. Thus, the first glass substrate 100 is not subject to the raised temperature environment despite the heat generated by the EL element 101. Accordingly, the accelerated deterioration of the EL element 101 is prevented.

Here, the total thickness of the desiccant layer 202 and the high heat conductive layer 203 is preferably as large as possible provided that the high heat conductive layer 203 does not contact the EL element 101 to the extent that the EL element 101 is damaged. Typically, the thickness is half the depth of the pocket portion 201, i.e., 0.1 to 0.2 mm. This is for thinning the N₂ gas layer 102 that has a low heat conductivity.

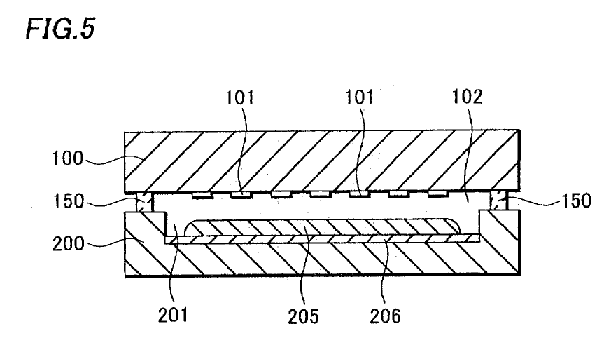

FIG. 4 is a cross-sectional view of an electroluminescent display device according to a second embodiment of the invention. FIG. 4 corresponds to a cross-sectional view along line A-A′ of FIG. 1.

Note that the same numerals are given to the same portions as those of FIG. 2.

In this embodiment, a high heat conductive material is mixed in the desiccant layer 205 formed on the pocket portion 201. The desiccant layer 205 is formed, for example, by mixing the high heat conductive material as well as powdered calcium oxide or barium oxide and a resin in a solvent. Conductive particles such as conductive fibers and carbon nanotubes are appropriate as the high heat conductive material.

A high content of the high heat conductive material in the desiccant layer 205 increases the heat conductivity of the desiccant layer 205. However, when the content is too high, the desiccant capacity is poor. When the content is too low, the heat conductivity is poor. Therefore, the content of the high heat conductive material is preferably 10 to 60 weight %.

According to the invention, heat generated upon light-emission of the EL element 101 is dissipated rapidly toward the second glass substrate 200 through the desiccant layer 205 having high heat conductivity. Thus, the temperature rise of the EL element 101 is prevented.

The thickness of the desiccant layer 202 is preferably as large as possible provided that the desiccant layer 202 does not contact the EL element 101 to the extent that the EL element 101 is damaged. Typically, the thickness is half the depth of the pocket portion 201, i.e., 0.1 to 0.2 mm. This is for thinning the N₂ gas layer 102 that has a low heat conductivity.

FIG. 5 is a cross-sectional view showing an electroluminescent display device according to a third embodiment of the invention. FIG. 5 corresponds to a cross-sectional view along line A-A′ of FIG. 1. Note that the same numerals are given to the same portions as those of FIG. 2.

The electroluminescent display device of this embodiment has a structure in which a high heat conductive layer 206 is formed on bottom of the pocket 201 of the second glass substrate 200 and the desiccant layer 202 is coated on the high heat conductive layer 206. The high heat conductive layer 206 is formed, for example, of a metal, such as Al and Cr, by sputtering, thermal spraying or vapor deposition. Its thickness is appropriately 20 to 30 micrometers.

In this structure, heat generated upon light-emission of the EL element 101 is dissipated rapidly toward the second glass substrate 200 through the high heat conductive layer 206. Thus, a temperature rise of the first glass substrate 100 is prevented.

The total thickness of the desiccant layer 202 and the high heat conductive layer 206 is preferably as large as possible provided that the desiccant layer 202 does not contact the EL element 101 to the extent that the EL element 101 is damaged. Typically, the thickness is half the depth of the pocket portion 201, i.e., 0.1 to 0.2 mm. This is for thinning the N₂ gas layer 102 that has a low heat conductivity.

Next, there will be described an example of structures of the pixel of the EL display device to be commonly applied to the first to third embodiments described above.

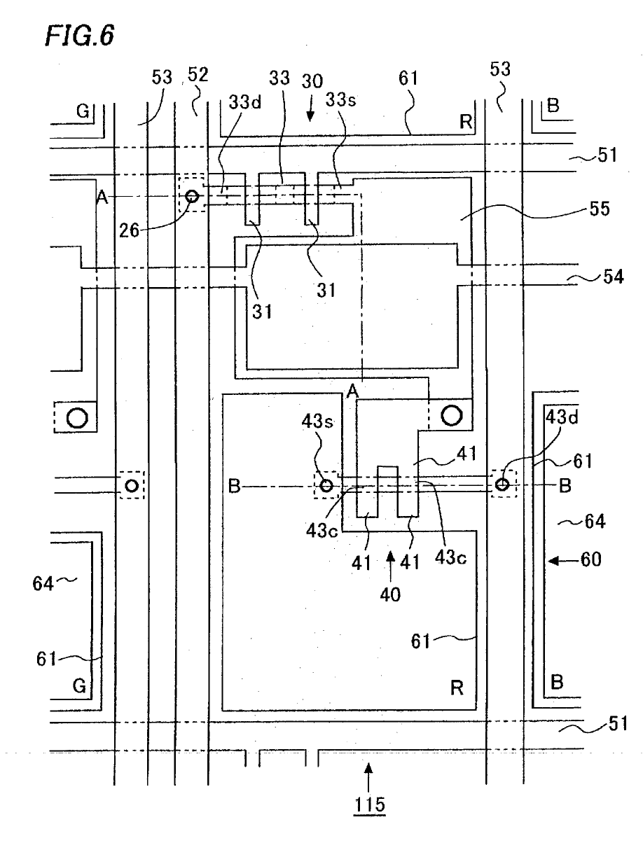

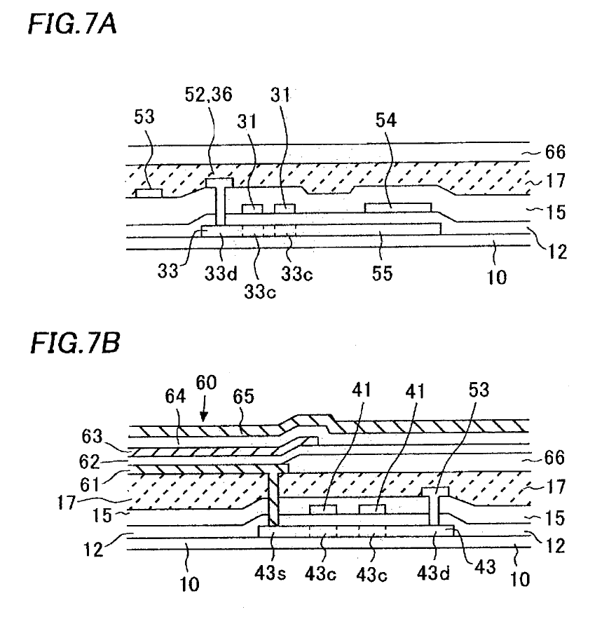

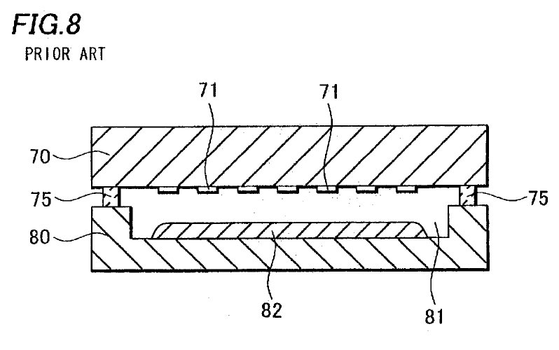

FIG. 6 is a plan view of a pixel of the organic EL display devices of the first, second and third embodiments. FIG. 7A is a cross-sectional view along line A-A of FIG. 6, and FIG. 7B is a cross-sectional view along line B-B of FIG. 6.

As shown in FIG. 6, a pixel 115 is formed in a region enclosed with a gate signal line 51 and a drain signal line 52. A plurality of the pixels 115 is disposed in a matrix.

There are disposed in the pixel 115 an organic EL element 60 as a self-emission element, a switching TFT (thin film transistor) 30 for controlling a timing of supplying an electric current to the organic EL element 60, a driving TFT 40 for supplying an electric current to the organic EL element 60 and a storage capacitor. The organic EL element 60 includes an anode 61, an emissive layer made of an emission material and a cathode 65.

The switching TFT 30 is provided in a periphery of a point of intersection of both signal lines 51 and 52. A source 33s of the switching TFT 30 serves as a capacitor electrode 55 for forming a capacitor with a storage capacitor electrode line 54 and is connected to a gate electrode 41 of the driving TFT 40. A source 43s of the driving TFT 40 is connected to the anode 61 of the organic EL element 60, while a drain 43d is connected to a driving source line 53 as a current source to be supplied to the organic EL element 60.

The storage capacitor electrode line 54 is disposed in parallel with the gate signal line 51. The storage capacitor electrode line 54 is made of Cr and forms a capacitor by storing electric charges with the capacitor electrode 55 connected to the source 33s of the TFT through a gate insulating film 12. The storage capacitor is provided for storing voltage applied to the gate electrode 41 of the driving TFT 40.

As shown in FIGS. 7A and 7B, the organic EL display device is formed by laminating the TFTs and the organic EL element sequentially on a substrate 10 made of a glass a synthetic resin, a conductive material, or a semiconductor. When using a conductive substrate or a semiconductor substrate as the substrate 10, however, an insulating film such as SiO₂ or SiNₓ is formed on the substrate 10, and then the switching TFT 30, the driving TFT 40 and the organic EL element 60 are formed thereon. Each of the two TFTs has a so-called top gate structure in which a gate electrode is disposed above an active layer with a gate insulating film being interposed therebetween.

There will be described the switching TFT 30 first. As shown in FIG. 7A, an amorphous silicon film (hereafter, referred to as an a-Si film) is formed on the insulating substrate 10 made of silica glass, non-alkali glass, etc by a CVD method etc. The a-Si film is irradiated by laser beams for melting and recrystalizing to form a poly-silicon film (hereafter, referred to as a p-Si film) as an active layer 33. On the active layer 33, a single-layer or a multi-layer of an SiO₂ film and an SiNₓ film is formed as the gate insulating film 12. There are disposed on the gate insulating film 12 the gate signal line 51 made of metal having a high melting point such as Cr and Mo (molybdenum) and also serving as a gate electrode 31, the drain signal line 52 made of Al, and the driving source line 53 made of Al and serving as a driving source of the organic EL element.

An interlayer insulating film 15 laminated with an SiO₂ film, an SiNₓ film and an SiO₂ film sequentially is formed on the whole surfaces of the gate insulating film 12 and the active layer 33. There is provided a drain electrode 36 by filling a contact hole provided correspondingly to a drain 33d with a metal such as Al. Furthermore, a planarization insulation film 17 for planarizing the surface which is made of an organic resin is formed on the whole surface.

Next, there will be described the driving TFT 40 of the organic EL element. As shown in FIG. 7B, an active layer 43 formed by poly-crystalizing an a-Si film by irradiating laser beams thereto, the gate insulating film 12, and the gate electrode 41 made of metal having a high melting point such as Cr and Mo are formed sequentially on the insulating substrate 10. There are provided in the active layer 43 a channel 43c, and a source 43s and a drain 43d on both sides of the channel 43c. The interlayer insulating film 15 laminated with an SiO₂ film, an SiNₓ film and an SiO₂ film sequentially is formed on the whole surfaces of the gate insulating film 12 and the active layer 43. There is disposed the driving source line 53 connected to a driving source by filling a contact hole provided correspondingly to a drain 43d with a metal such as Al. Furthermore, a planarization insulation film 17 for planarizing a surface, which is made of, for example, an organic resin is formed on the whole surface. A contact hole is formed in a position corresponding to a source 43s in the planarization insulation film 17. There is formed on the planarization insulation film 17 a transparent electrode made of ITO (Indium Tin Oxide) and contacting to the source 43s through the contact hole, i.e., the anode 61 of the organic EL element. The anode 61 is formed in each of the pixels, being isolated as an island.

The organic EL element 60 has a structure of laminating sequentially the anode 61 made of a transparent electrode such as ITO, a hole transport layer 62 including a first hole transport layer made of MTDATA (4,4-bis(3-methylphenylphenylamino)biphenyl), and a second hole transport layer made of TPD (4,4,4-tris(3-methylphenylphenylamino) triphenylanine), an emissive layer 63 made of Bebq₂ (bis(10-hydroxybenzo[h]quinolinato)beryllium) containing a quinacridone derivative, an electron transport layer 64 made of Bebq₂, and a cathode 65 made of magnesium-indium alloy, aluminum or aluminum alloy.

A second planarization insulation film 66 is formed on the planarization insulation film 17. The second planarization insulation film 66 is removed on the anode 61.

In the organic EL element 60, a hole injected from the anode 61 and an electron injected from the cathode 65 are recombined in the emissive layer and an exciton is formed by exciting an organic module forming the emissive layer 63. Light is emitted from the emissive layer 63 in a process of radiation of the exciton and then released outside after going through the transparent anode 61 and the transparent insulating substrate 10, thereby to complete a light-emission.

What is claimed is:

1. An electroluminescent display device comprising:
a first substrate having an electroluminescent element thereon;
a second substrate attached to the first substrate;
a desiccant layer disposed on the second substrate so that the desiccant layer faces the first substrate; and
a heat dissipation layer disposed on the desiccant layer and having a high thermal conductivity.

2. The electroluminescent display device of claim 1, wherein the heat dissipation layer comprises a metal sheet.

3. The electroluminescent display device of claim 1, wherein the heat dissipation layer includes a plurality of air vents.

4. The electroluminescent display device of claim 2, wherein the heat dissipation layer includes a plurality of air vents.

5. The electroluminescent display device of claim 1, wherein the second substrate includes a concave portion and the desiccant layer is disposed in the concave portion.

6. The electroluminescent display device of claim 1, wherein an inert gas fills a space between the first substrate and the heat dissipation layer.

7. An electroluminescent display device comprising:
a first substrate having an electroluminescent element thereon;
a second substrate attached to the first substrate; and
a desiccant layer disposed on the second substrate so that the desiccant layer faces the first substrate, the desiccant layer including a material of a high thermal conductivity.

8. The electroluminescent display device of claim 7, wherein the material of a high thermal conductivity is a material with electronic conductivity, and the material with electronic conductivity is disposed in the desiccant layer as particles.

9. The electroluminescent display device of claim 8, wherein the particles are electrically conductive particles.

10. The electroluminescent display device of claim 8, wherein the particles are carbon nanotubes.

11. The electroluminescent display device of claim 7, wherein an inert gas fills a space between the first substrate and the desiccant layer.

12. An electroluminescent display device comprising:
a first substrate having an electroluminescent element thereon;
a second substrate attached to the first substrate;
a heat dissipation layer disposed on the second substrate so that the heat dissipation layer faces the first substrate, the heat dissipation layer having a high thermal conductivity; and
a desiccant layer disposed on the heat dissipation layer.

13. The electroluminescent display device of claim 12, wherein the second substrate includes a concave portion and the heat dissipation layer is disposed in the concave portion.

14. The electroluminescent display device of claim 12, wherein the heat dissipation layer comprises a metal sheet.

15. The electroluminescent display device of claim 13, wherein the heat dissipation layer comprises a metal sheet.

16. The electroluminescent display device of claim 12, wherein an inert gas fills a space between the first substrate and the desiccant layer.

17. An electroluminescent display device comprising:
a first substrate having an electroluminescent element thereon;
a second substrate attached to the first substrate; and
means for dissipating heat generated by the electroluminescent element.
